(19) United States
(12) Patent Application Publication
(10) Pub. No.: US 2025/0264795 A1
(43) Pub. Date: Aug. 21, 2025

(54) PELLICLE MEMBRANE FOR A LITHOGRAPHIC APPARATUS

(71) Applicant: ASML NETHERLANDS B.V., Veldhoven (NL)

(72) Inventors: Zomer Silvester HOUWELING, Utrecht (NL); Inci DONMEZ NOYAN, Eindhoven (NL)

(73) Assignee: ASML NETHERLANDS B.V., Veldhoven (NL)

(21) Appl. No.: 18/854,053

(22) PCT Filed: Mar. 17, 2023
(86) PCT No.: PCT/EP2023/056949

§ 371 Date: Oct. 3, 2024

(30) Foreign Application Priority Data
Apr. 22, 2022 (EP) 22169417.7
Oct. 7, 2022 (EP) 22200334.5

(51) Int. Cl. G03F 1/62; C23C 14/06; C23C 14/34

(52) U.S. Cl. CPC G03F 1/62; C23C 14/0623; C23C 14/0682; C23C 14/3464

(57) ABSTRACT

A pellicle membrane including emissive crystals in a matrix containing at least one element which forms a chemical bond with silicon having a bond dissociation energy of at least 447 kJ mol⁻¹. A method of manufacturing such a pellicle membrane, a pellicle assembly including such a pellicle membrane and a lithographic apparatus including such a pellicle assembly or pellicle membrane. Also the use of molybdenum silicon sulphide, oxide, selenide, or fluoride in a pellicle membrane. The use of such a pellicle membrane, pellicle assembly or lithographic apparatus in a lithographic apparatus or method.

### CROSS-REFERENCE TO RELATED APPLICATIONS

This application claims priority of EP Application Serial No. 22169417.7 which was filed on Apr. 22, 2022 and EP Application Serial No. 22200334.5 which was filed on Oct. 7, 2022 and which are incorporated herein in their entirety by reference.

### FIELD

The present invention relates to a pellicle membrane for a lithographic apparatus, an assembly for a lithographic apparatus, methods of manufacturing a pellicle membrane, use of molybdenum silicon sulfide, oxide, selenide, or fluoride in a pellicle membrane, and a use of a pellicle membrane in a lithographic apparatus or method.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

A mask assembly may include the pellicle which protects a patterning device (e.g. a mask) from particle contamination. The pellicle may be supported by a pellicle frame, forming a pellicle assembly. The pellicle may be attached to the frame, for example, by gluing or otherwise attaching a pellicle border region to the frame. The frame may be permanently or releasably attached to a patterning device.

Due to the presence of the pellicle in the optical path of the EUV radiation beam, it is necessary for the pellicle to have high EUV transmissivity. A high EUV transmissivity allows a greater proportion of the incident radiation through the pellicle. In addition, reducing the amount of EUV radiation absorbed by the pellicle may decrease the operating temperature of the pellicle. Since transmissivity is at least partially dependent on the thickness of the pellicle, it is desirable to provide a pellicle which is as thin as possible whilst remaining reliably strong enough to withstand the sometimes hostile environment within a lithography apparatus.

It is therefore desirable to provide a pellicle which is able to withstand the harsh environment of a lithographic apparatus, in particular an EUV lithography apparatus. It is particularly desirable to provide a pellicle which is able to withstand higher powers than previously. It is also desirable to provide pellicle membranes which limit or eliminate contamination of the lithographic apparatus due to release of material from the pellicle membrane, which can be referred to as hydrogen-induced outgassing.

Whilst the present application generally refers to pellicles in the context of lithography apparatus, in particular EUV lithography apparatus, the invention is not limited to only pellicles and lithography apparatus and it is appreciated that the subject matter of the present invention may be used in any other suitable apparatus or circumstances.

For example, the methods of the present invention may equally be applied to spectral purity filters. Some EUV sources, such as those which generate EUV radiation using a plasma, do not only emit desired ‘in-band’ EUV radiation, but also undesirable (out-of-band) radiation. This out-of-band radiation is most notably in the deep UV (DUV) radiation range (100 to 400 nm). Moreover, in the case of some EUV sources, for example laser produced plasma EUV sources, the radiation from the laser, usually at 10.6 microns, presents a significant out-of-band radiation.

In a lithographic apparatus, spectral purity is desired for several reasons. One reason is that the resist is sensitive to out of-band wavelengths of radiation, and thus the image quality of patterns applied to the resist may be deteriorated if the resist is exposed to such out-of-band radiation. Furthermore, out-of-band radiation infrared radiation, for example the 10.6 micron radiation in some laser produced plasma sources, leads to unwanted and unnecessary heating of the patterning device, substrate, and optics within the lithographic apparatus. Such heating may lead to damage of these elements, degradation in their lifetime, and/or defects or distortions in patterns projected onto and applied to a resist-coated substrate.

A typical spectral purity filter may be formed, for example, from a silicon foundation structure (e.g. a silicon grid, or other member, provided with apertures) that is coated with a reflective metal, such as molybdenum. In use, a typical spectral purity filter might be subjected to a high heat load from, for example, incident infrared and EUV radiation. The heat load might result in the temperature of the spectral purity filter being above 800° C. Under the high head load, the coating can delaminate due to a difference in the coefficients of linear expansion between the reflective molybdenum coating and the underlying silicon support structure. Delamination and degradation of the silicon foundation structure is accelerated by the presence of hydrogen, which is often used as a gas in the environment in which the spectral purity filter is used in order to suppress debris (e.g. debris, such as particles or the like), from entering or leaving certain parts of the lithographic apparatus. Thus, the spectral purity filter may be used as a pellicle, and vice versa. Therefore, reference in the present application to a ‘pellicle’ is also reference to a ‘spectral purity filter’. Although reference is primarily made to pellicles in the present application, all of the features could equally be applied to spectral purity filters.

The present invention has been devised in an attempt to address at least some of the problems identified above.

### SUMMARY OF THE INVENTION

According to a first aspect of the present disclosure, there is provided a pellicle membrane comprising emissive crystals in a matrix containing at least one element which forms a chemical bond with silicon having a bond dissociation energy of at least 447 kJ mol⁻¹ or at least 4.6 eV.

The selection of materials for a pellicle membrane are selected based on criteria such as thermodynamic reduction and oxidation stability, hydride formation, volatalization tendency, EUV transmissivity, EUV resistance, heat resistance, amongst others. It has been found that the bond dissociation energy of the materials forming the pellicle membrane is also an important selection criterion. In particular, the presence of bonds in the matrix which are stronger than silicon-carbon bonds (3.6 eV), means that movement, and ultimately outgassing of material such as silicon from the membrane is attenuated. Without wishing to be bound by scientific theory, it is believed that the bonds in the matrix material are less readily released by bond-breaking events and consequently exhibit less and slower diffusion. In other words, the desired bond dissociation energy according to the present disclosure is equal to or greater than the bond dissociation energy of silicon and carbon plus 1 eV, i.e. 3.6 eV+1 eV=4.6 eV, which equates to 447 kJ mol⁻¹ or more.

Elements which are able to form bonds of such strength with silicon include sulphur, oxygen, selenium, and fluorine. In other terms, the minimum bond dissociation energy may be 4.6 eV.

It has been found that a pellicle membrane including metal silicide crystals in a sulphur-containing matrix exhibits higher EUV transmissivity than an otherwise equivalent pellicle membrane comprising a nitride, for example molybdenum silicide nitride. In addition, the Si—S bonds in the pellicle membrane matrix have a higher bond-dissociation energy than Si—N bonds in a pellicle membrane matrix comprising nitride. Whilst oxygen, selenium, and fluorine have higher EUV absorption coefficients than nitrogen or amorphous carbon, the bond dissociation energies of oxygen, selenium and fluorine with silicon are greater than those of nitrogen and amorphous carbon with silicon, so there will be less outgassing of material from the pellicle membrane, albeit at the potential cost of transmissivity. The higher bond dissociation energy results in fewer bond breaking events when photons are incident on the pellicle membrane. This has the consequence that there is less migration of materials, such as silicon through the matrix material to the outer surface of the pellicle membrane, which in turn leads to less outgassing of such materials, such as silicon. In addition, as compared to pellicle membranes which rely on a matrix comprising essentially only silicon, during synthesis of a pellicle membrane according to the present disclosure, there is less silicon available for incorporation into the metal silicide crystals. This results in the formation of crystals which are more metal-rich, which is assessed to provide the pellicle membrane according to the present disclosure higher thermal emissivity than a membrane of the same thickness that includes a silicon matrix. Sulphur has a lower EUV absorption coefficient as compared to nitrogen and carbon, and also has a higher bond dissociation energy, so the sulphur bonds are less likely to break in use. Whilst silicon has a lower EUV absorption coefficient than sulphur, it has a lower bond dissociation energy and so is more likely to result in outgassing of silicon. Furthermore, sulphur is not suspected to contribute greatly to the contamination of optics within lithographic apparatuses.

The sulphur-containing matrix may comprise silicon sulphide. The sulphur-containing matrix may consist of silicon sulphide. The matrix may include or consist of silicon oxide, silicon selenide, or silicon fluoride, or a combination of one or more of any of the matrix materials described herein. An embodiment of the present invention includes a pellicle membrane comprising metal silicide crystals in a sulphur-containing matrix wherein the matrix comprises silicon sulphide.

The emissive crystals may include one or more of a metal carbide, a metal boride, a metal nitride, a metal fluoride, a metal silicide, or a metal. The metal (which may be the metal is any of the aforementioned compounds or elemental metal) may be selected from one or more of molybdenum zirconium, yttrium, lanthanum, scandium, niobium, iridium, chromium, vanadium, platinum, rhodium, hafnium, and ruthenium. Yttrium oxide, zirconium oxide, hafnium oxide, and carbon nitride show particular potential as matrix materials for pellicle membranes since they have ultimate tensile strengths similar to that of silicon and include bonds with bond dissociation energies greater than 4.6 eV. Molybdenum silicide crystals are more emissive than silicon and so contribute to increasing the emissivity of the pellicle membrane, thereby reducing the operating temperature of the membrane at a given power. Similarly, other emissive crystals according to the present disclosure serve to increase the emissivity of the pellicle membrane, thereby reducing the operating temperature of the membrane at a given power.

The emissive crystals may include one or a combination of Mo₅Si₃ and Mo₃Si. This provides the crystals with an increased proportion of metal, thereby increasing the emissivity of such metal silicide crystals.

The emissive crystals may comprise metal silicide having a composition of MoSi₂₋ₓ, wherein 0≤x<2. In cases where the metal silicide is relatively metal rich, the emissivity is increased and the amount of silicon, which can migrate through the pellicle membrane and be outgassed, is reduced. It will be appreciated that molybdenum disilicide crystals may be used as the inclusion of sulphur in the matrix serves to reduce the overall amount of silicon in the pellicle membrane.

The sulphur-containing matrix may have a composition of SiS_{2-y}, wherein 0≤y<2. The inclusion of sulphur within the pellicle membrane is believed to reduce outgassing by bonding the sulphur to the silicon strongly, thereby inhibiting silicon migration and outgassing.

The pellicle membrane may at least partially have the formula MoₐSi_{b}S_{c}, wherein 0<a≤ 30, 50≤b≤90, and 0<c≤50, (by mole %). In embodiments, 10≤a≤30, (by mole %). In embodiments, 60≤b≤70, (by mole %). In embodiments, 20≤c≤30, (by mole %). The thermodynamic stability of the pellicle membrane can depend on the relative amounts of the metal, silicon and sulphur. The amount of molybdenum provides a suitable level of emissivity without sacrificing transmissivity. The amount of sulphur is controlled to avoid the formation of gaseous phases at certain temperatures and to also avoid unwanted oxidation. The amount of silicon is controlled to provide sufficient strength to the pellicle membrane whilst reducing the likelihood of outgassing of silicon. The pellicle membrane May at least partially comprise MoSiN, or MoSiSi.

The pellicle membrane may include silicon and metal, preferably molybdenum, and the ratio (by mole %) of Si:Metal (Mo) may deviate from 2.0. In other words, the Si:Metal ratio is lower than the stoichiometric value, namely that there is less than the stoichiometric value of silicon. In this way, the pellicle membrane is relatively metal rich, which increases the emissivity of the pellicle membrane whilst also reducing the likelihood of silicon outgassing. This also allows for a thinner membrane than would be the case with a stoichiometric amount of silicon to molybdenum.

The pellicle membrane may have an EUV transmissivity of 90% or greater at a single pass.

The thickness of the pellicle membrane may be from about 10 nm to about 100 nm. The thickness of the pellicle membrane is preferably 18 nm or less. In particular, where the element which forms the bond with silicon having a bond dissociation energy of greater than 447 kJ mol⁻¹ is from group VIA of the periodic table, specifically oxygen, sulphur, or selenium, in order to have no free silicon in the membrane matrix, the thickness of the membrane must not exceed 18 nm. In embodiments, the thickness of the pellicle membrane is 15 nm or less. In particular, where the element which forms the bond with silicon having a bond dissociation energy of greater than 447 kJ mol⁻¹ is from group VIIA of the periodic table, specifically fluorine, in order to have no free silicon in the membrane matrix, the thickness of the membrane must not exceed 15 nm.

The membrane may consist of molybdenum silicide crystals in a silicon sulphide, oxide, selenide, or fluoride matrix. It will be appreciated that unintentional minor contaminants may be present due to manufacturing and materials tolerances. The contaminants may be present in amounts which are inconsequential to the performance of the membrane. In such embodiments, additional elements are not intentionally included.

The pellicle membrane may include a core of MoSiN, MoSiSi, or MoSiC with a capping layer comprising any of the materials described in the first aspect of the present disclosure. Such a capping layer does not necessarily have to be the outermost layer, and there may be another cap layer that protects the capping layer from the lithographic environment.

According to a second aspect of the present disclosure, there is provided a method of manufacturing a pellicle membrane according to the first aspect of the present disclosure, wherein the method includes sputtering, optionally co-sputtering.

Sputtering, preferably co-sputtering, provides for the exact composition of a pellicle membrane to be controlled, thereby allowing the manufacture of a pellicle membrane according to the present disclosure.

According to a third aspect of the present disclosure, there is provided a pellicle assembly comprising a pellicle membrane according to the first aspect of the present disclosure. The pellicle assembly may include additional elements as conventionally found in pellicle assemblies. For example, the pellicle assembly may include a frame via which the pellicle membrane may be supported.

According to a fourth aspect of the present disclosure, there is provided a lithographic apparatus comprising a pellicle membrane according to the first aspect or a pellicle assembly according to the third aspect of the present disclosure.

According to a fifth aspect of the present invention, there is provided the use of molybdenum silicon sulphide, oxide, selenide, or fluoride in a pellicle membrane.

The pellicle membrane may be the pellicle membrane according to any aspect of the present disclosure. In embodiments, the pellicle membrane may at least partially have the formula MoₐSi_{b}S_{c}, wherein 0<a≤30, 50≤b≤90, and 0<c≤50, (by mole %).

According to a sixth aspect of the present invention, there is provided the use of a pellicle membrane, pellicle assembly, or lithographic apparatus according to the first, third or fourth aspect of the present disclosure in a lithographic apparatus or method.

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the invention; and

FIG. 2 depicts a pellicle assembly with a composite film.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

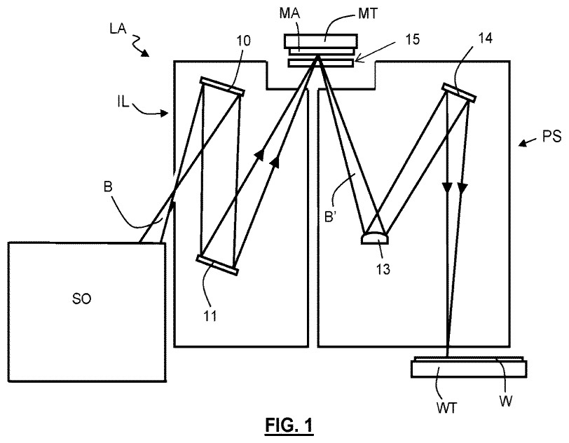

FIG. 1 shows a lithographic system including a pellicle 15 (also referred to as a membrane assembly) according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, the pellicle 15 is depicted in the path of the radiation and protecting the patterning device MA. It will be appreciated that the pellicle 15 may be located in any required position and may be used to protect any of the mirrors in the lithographic apparatus.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 of the present invention can be used for a dynamic gas lock or for a pellicle or for another purpose. In an embodiment the membrane assembly 15 comprises a membrane formed from the at least one membrane layer having an emissivity of 0.3 or more. In order to ensure maximized EUV transmission and minimized impact on imaging performance it is preferred that the membrane is only supported at the border.

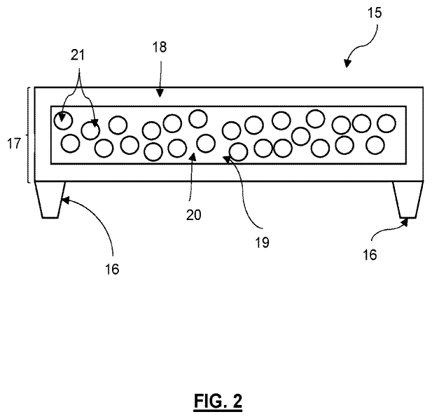

FIG. 2 is a schematic depiction of a pellicle assembly 15 in accordance with the present disclosure. The pellicle assembly includes a support 16 that is configured to support the pellicle membrane 17. In the figure, the support 16 appears as two separate elements, although this does not necessarily have to be the case and the support 16 may be in the form of a border which circumscribes the pellicle membrane 17. The pellicle membrane 17 includes a cap layer 18 that is configured to protect the pellicle membrane 17, particularly the emissive layer 19, from degradation. The cap layer may be any known cap layer and the present disclosure is not particularly limited to any specific cap layer material. The emissive layer 19 includes a matrix 20, which provides the required pre-tension and strength. Pre-tension is required since the pellicle membrane 17 is subjected to a pressure differential in use and it is necessary to accommodate such a differential. The matrix material 20 may include one or more of elemental silicon, silicon oxide, silicon fluoride, silicon sulphide, or silicon selenide. The emissive layer 19 includes thermally emissive crystals 21 disposed within the matrix 20. The thermally emissive crystals 21 are includes to increase the thermal emissivity of the pellicle membrane 17, thereby allowing it to operate at a lower temperature at a given power than would be the case otherwise, or to operate at the same temperature as pellicle membranes not including emissive crystals, but at a higher power. The thermally emissive crystals 21 may include one or more of a metal carbide, a metal boride, a metal nitride, a metal fluoride, a metal silicide, or a metal. The metal may be selected from one or more of molybdenum, zirconium, yttrium, lanthanum, scandium, niobium, iridium, chromium, vanadium, platinum, rhodium, hafnium, and ruthenium.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

The present invention targets an attenuation of hydrogen-induced outgassing (HIO) of Si-containing species from Metal Silicide-based Composite (MSC) EUV pellicles under EUV scanner operation conditions. In embodiments, the MSC pellicle comprises a dual composition of emissive metal-silicide (MoSiₓ) crystals and a flexible and strength-providing matrix consisting of a compound in which Silicon is bound to a secondary element “ψ”, called the Si-ψ_{y} matrix. A MSC material-selection parameter may be the “bond dissociation energy (BDE)” of Si-ψ bonds in the matrix. The BDE of Si-ψ bonds in the matrix governs the breaking of Si-ψ bonds during scanner exposure, which generates free Si species that can diffuse to the external pellicle surface, where it can exit the pellicle via HIO processes. A high Si-BDE thus results in attenuated HIO processes. The BDE as a parameter to select MSC pellicle materials is described herein.

An aspect of the invention is a new EUV pellicle composite MoSi-ψ material combination, with ψ=S, O, Se or F. The composite layer has a dual composition of MoSi, crystals and a Si-ψ_{y} material matrix. For instance, in the case of ψ=S, the Si-S_{2-y} matrix material may exhibit even higher EUV transmission (EUVT) than for commercially available composite pellicles. For example Si—S bonds in the matrix have a higher bond dissociation energy (BDE) than Si—N in an SiN matrix; as stated a high BDE results in less bond breaking events when photons are incident on the material and may result in a smaller amount of migration of Si through the matrix material to the outer surfaces, which consequently results in less Si outgassing. Based on the BDE of Si—S, as well as other compositions described herein, the pellicle membrane of the present disclosure exhibits reduced outgassing compared to other composite pellicle solutions such as MoSiN, MoSiSi and MoSiC.

In addition, in comparison to the MoSi-ψ concept with ψ=Si, which a has Si(—Si) as matrix, the MoSiS embodiment described herein has Si—S_{2-y}, as matrix, which entails that during the synthesis of the material (which includes emissive MoSiₓ crystals in a tensile core), there is less Si available for incorporation in the MoSiₓ crystals allowing for the formation of crystals that are richer in Mo content, which provides the new composite a higher thermal emissivity than MoSiSi layers of equal thickness. The crystals in the MoSi—S pellicle can be engineered to comprise of Mo-rich Mo₅Si₃, since some of the Si binds to the matrix and not to the emissive crystals, whereas for the poorly emitting MoSiSi this cannot occur and the crystals comprise of MoSi₂, of lower Mo content.

Additional features of the pellicle membrane according to the present disclosure include:
A power capability of ≥600 W. That is to say that the pellicle membrane is able to operate under power conditions of 600 W or greater; and/or
An EUV transmission value of 90% or greater in a single-pass.

A threshold BDE-value is defined here as any value greater than Si—N and Si—C and Si—Si bonds.

Experiments showed that the metallic content of the embedded core crystals is important for emissivity. For a MoSiψ membrane with sufficient emissivity, the MoSi crystal composition may be [Si]/[Mo]=0.6 for Mo₅Si₃, or [Si]/[Mo]=0.3 for the other available Mo-rich phase Mo₃Si. If the composition of the Mo phase is [Si]/[Mo]=2.0 for MoSi₂ then the film thickness is preferably larger than ˜20 nm (for low Mo concentrations the film needs to be thicker). The matrix material for a composite should contain sufficient Si, which comes at the expense of Si incorporation in the core crystals. However, preferably the matrix should not comprise exclusively Si, such as for MoSiSi type composites.

Related to the bond dissociation energy (BDE) of element w with Si and the migration and successive outgassing of Si atoms, if the Si-ψ BDE is sufficiently strong then Si migration is inhibited and outgassing can only temporarily occur until the external region of the pellicle is depleted of Si. Excessive Si is able to migrate through the membrane and can be released at the external regions of the membrane in a number of processes denoted as said Si outgassing (such as SiO₂ desorption or SiH₄ formation. A MoSiψ concept as described herein with potential low levels of outgassing thus exhibits a high Si-ψ bond energy, such that bond dissociation is limited and with that also the migration of atoms of Si through the Siψ₂₋ₓ matrix is limited as well as the outgassing. For a composite pellicle that is not based on a silicide the requirement for a minimum value of BDE is different.

A value of at most 1.1·10¹⁵ at.·cm⁻² outgassed Si atoms per 10000 scanner wafers is taken here as an exemplary specification of acceptable HIO amount, which entails at most 0.55·10¹⁵ at.·cm⁻² outgassed Si atoms per 10000 scanner wafers for each pellicle side.

Among the crucial parameters that determine whether a volatile species poses a risk for reducing the optical performance of an EUV mirror is firstly the sticking probability of that species to the surface of the EUV mirror and secondly whether the species oxidizes on the surface of the mirror.

As a minimum, the BDE value the Si—C bond is considered as that is the highest BDE value of the three composite pellicle varieties of MoSiC, MoSiSi and MoSiN, which all exhibit outgassing of Si, which is hypothesized here to be related to atomic migration. As such, the BDE value of the atom bonds are preferably larger to reduce bond breaking events and to thus attenuate consequent atom migration. The present invention claims that for any improvement the BDE must exceed that “SiC+1 eV” value. For silicides in general the EUV transmissivity is highest, next for carbides, then borides, then nitrides, then oxides, then fluorides, then sulfides, then “other bonds” such as BCl—O, HCN, HC—CH and C—O.

Emissive crystals may be for example one or more of the following materials: metal carbides (such as Mo2C), metal borides (such as ZrB2, MoB2), metal silicides (such as ZrSi2, MoSi2, YSi2, LaSi2, ScSi2, NbSi2, RuSi2), or metals (such as Mo, Ru, Sc).

Such emissive crystals may be combined with matrix materials which (if so required) can provide pre-tension and strength, for example a nitride, oxide, fluoride or sulfide, depending on the required pre-tension and EUV transmission.

Materials of high interest as pellicle core include Y2O3, ZrO2, HfO2 and especially C3N4, which all have ultimate tensile strength (UTS) values comparable to Si. The latter C3N4 has extremely high UTS values. “Other bonds” may include BCl—O, HCN, HC—CH and C—O; such bonds can be very useful for termination or passivation of a pellicle surface as these have extremely high BDE's.

According to the present invention, by providing metal silicide crystals in a sulphur-containing matrix, it is possible to reduce silicon outgassing whilst retaining EUV transmissivity which is higher than equivalent pellicle membranes. In particular, a molybdenum silicide sulphide pellicle membrane includes molybdenum silicide crystals in a silicon sulphide matrix. The strong silicon-sulphur bonds have a higher bond dissociation energy than silicon-nitrogen or silicon-silicon bonds, and so when the pellicle membrane is illuminated with EUV light, there is a lower likelihood of bond dissociation, which leads to silicon migration and outgassing. Sulphur is not strongly associated with contamination of optics within a lithography apparatus and so does not present a significant contamination concern if some sulphur is outgassed. Furthermore, as compared to a silicon only matrix, silicon sulphide has proportionally less silicon available to be incorporated into the molybdenum silicide crystals which allows for the formation of more Mo-rich crystals, which is considered to provide higher emissivity. Indeed, it is preferable that the composition of the molybdenum phase is more molybdenum rich than the stoichiometric value. In other words the ratio of Si:Mo should be less than 2.0. This allows the pellicle membrane to be thinner than would be the case were the molybdenum phase to consist of MoSi₂.

The present invention may allow for uncapped pellicle membranes due to the reduced propensity for silicon outgassing.

The pellicle membrane according to the present disclosure may be manufactured via sputtering. Sputtering a molybdenum silicide target and a silicon sulphide target results in a pellicle membrane having metal rich molybdenum silicide crystals in a silicon sulphide matrix. Similarly, reactive sputtering of molybdenum disilicide in a hydrogen sulphide atmosphere results in a pellicle membrane of the present disclosure. By providing sulphur in the matrix, the bonds to silicon are strong and silicon outgassing may only be observed until the external region of the pellicle membrane is depleted of silicon which is liable to outgas. It is considered that silicon migration is inhibited by the strong bond to sulphur.

As such, the present disclosure provides for pellicle membranes which have similar or better transmissivity as compared to other pellicle membranes, but which have lower amounts of silicon outgassing as well as acceptable EUV transmissivity, and also acceptable emissivity, which allows them to operate within lithographic apparatuses, particularly EUV apparatuses.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

1. A pellicle membrane comprising emissive crystals in a matrix comprising at least one element which forms a chemical bond with silicon having a bond dissociation energy of at least 447 kJ mol⁻¹ or at least 4.6 eV.

2. The pellicle membrane according to claim 1, wherein the matrix comprises silicon.

3. The pellicle membrane according to claim 1, wherein the emissive crystals include one or more selected from: a metal carbide, a metal boride, a metal nitride, a metal fluoride, a metal silicide, or a metal selected from one or more selected from: molybdenum, zirconium, yttrium, lanthanum, scandium, niobium, iridium, chromium, vanadium, platinum, rhodium, hafnium, and/or ruthenium.

4. The pellicle membrane according to claim 3, wherein the crystals include one or a combination of Mo₅Si₃ and Mo₃Si.

5. The pellicle membrane according to claim 3, wherein the crystals comprise molybdenum silicide having a composition of MoSi₂₋ₓ, wherein 0≤x<2.

6. The pellicle membrane according to claim 1, wherein the matrix has a composition of SiS_{2-y}, wherein 0≤y<2.

7. The pellicle membrane according to claim 1, wherein the pellicle membrane at least partially has the formula MoₐSi_{b}S_{c}, wherein 0<a≤30, 50≤b≤90, and 0<c≤50, (by mole %).

8. The pellicle membrane according to claim 7, wherein 10≤a≤30, (by mole %).

9. The pellicle membrane of claim 7, wherein 60≤b≤70, (by mole %).

10. The pellicle membrane of claim 7, wherein 20≤c≤30, (by mole %).

11. The pellicle membrane of claim 1, wherein the pellicle membrane includes silicon and molybdenum and the ratio (by mole %) of Si:Mo deviates from 2.0.

12. The pellicle membrane according to claim 1, wherein the pellicle membrane has an EUV transmissivity of 90% or greater at a single pass.

13. The pellicle membrane according to claim 1, wherein the thickness of the pellicle membrane is from about 10 nm to about 100 nm.

14. The pellicle membrane according to claim 1, wherein the membrane consists of molybdenum silicide crystals in a silicon sulphide, oxide, selenide, or fluoride matrix.

15. A method of manufacturing the membrane according to claim 1, wherein the method includes sputtering.

16. A pellicle assembly comprising a frame and the pellicle membrane according to claim 1.

17. A lithographic apparatus comprising the pellicle membrane according to claim 1.

18. A pellicle membrane comprising Use of molybdenum silicon sulphide, oxide, selenide, or fluoride in a pellicle membrane.

19. The pellicle membrane of claim 18, comprising molybdenum silicon sulphide, wherein material of the pellicle membrane has the formula MoₐSi_{b}S_{c}, wherein 0<a≤30, 50≤b≤90, and 0<c≤50, (by mole %).

20. A method comprising exposing to radiation the pellicle membrane according to claim 1 in a lithographic apparatus or method.
